(19) United States
(12) Patent Application Publication
(10) Pub. No.: US 2025/0309745 A1
(43) Pub. Date: Oct. 2, 2025

(54) POWER MODULE

(71) Applicant: Asahi Kasei Microdevices Corporation, Tokyo (JP)

(72) Inventor: Kenji KURIYAMA, Tokyo (JP)

(21) Appl. No.: 19/090,390

(22) Filed: Mar. 26, 2025

(30) Foreign Application Priority Data
Mar. 27, 2024 (JP) 2024-051455
Mar. 12, 2025 (JP) 2025-038847

(51) Int. Cl. H02M 1/00; G01R 33/07; H01L 23/538; H01L 25/07; H01L 25/18; H02M 7/00; H02M 7/539

(52) U.S. Cl. CPC H02M 1/0009; G01R 33/072; H01L 23/5386; H01L 25/072; H01L 25/18; H02M 7/003; H02M 7/539

(57) ABSTRACT

A power module may include; a first power semiconductor mounted on an insulating substrate; a first conductor at least partially overlapped with the first power semiconductor in a plan view, electrically coupled to a first terminal of the first power semiconductor, and extending along a surface of the insulating substrate in a first direction; a current sensor which is arranged to be at least partially overlapped with or at least partially surrounded by the first conductor in the plan view,; an encapsulating portion which encapsulates them, in a state in which the first conductor and the current sensor are insulated from each other; and a first external terminal electrically coupled to the first conductor and exposed from the encapsulating portion. The current sensor may be arranged between the first external terminal and the first power semiconductor in the first direction in the plan view.

The contents of the following patent application(s) are incorporated herein by reference:
NO. 2024-051455 filed in JP on Mar. 27, 2024
NO. 2025-038847 filed in JP on Mar. 12, 2025.

### BACKGROUND

### 1. Technical Field

The present invention relates to a power module.

### 2. Related Art

Patent document 1 describes mounting a magnetic sensor on a substrate on which a semiconductor die such as an IGBT is mounted. Patent document 2 describes arranging a current sensor at a position facing each conductor that outputs three-phase AC power. Patent document 3 describes fixing a current sensor module to a frame on which a substrate, on which a power semiconductor is mounted, is installed.

### PRIOR ART DOCUMENTS

### Patent Documents

Patent Document 1: Specification of U.S. Pat. No. 9,678,173

Patent Document 2: Japanese Patent Application Publication No. 2023-138260

Patent Document 3: Specification of U.S. Patent Application Publication No. 2022/0262773

### BRIEF DESCRIPTION OF THE DRAWINGS

FIG. 1 illustrates an example of a circuit configuration of a power module according to the present embodiment.

FIG. 2 is a plan view schematically illustrating an example of an internal configuration of the power module according to the present embodiment.

FIG. 3 schematically illustrates a part of a cross-sectional view of the power module viewed from a side surface side in an X direction.

FIG. 4 is a perspective view schematically illustrating a current sensor, a conductor, and an input/output conductor.

FIG. 5 is a drawing according to a modified example schematically illustrating a part of a cross-sectional view of the power module from the side surface side in the X direction.

FIG. 6 is a perspective view schematically illustrating the current sensor, the conductor, and the input/output conductor in the modified example illustrated in FIG. 5.

FIG. 7A illustrates an example of a shape of the conductor.

FIG. 7B illustrates an example of a shape of the conductor.

FIG. 7C illustrates an example of a shape of the conductor.

FIG. 7D illustrates an example of a shape of the conductor.

FIG. 8 illustrates an example of an installation mode of the current sensor according to a modified example.

FIG. 9 illustrates an example of an installation mode of the current sensor according to a modified example.

FIG. 10 schematically illustrates an example of an internal configuration of the power module according to a modified example.

FIG. 11 schematically illustrates an example of an internal configuration of the power module according to a modified example.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

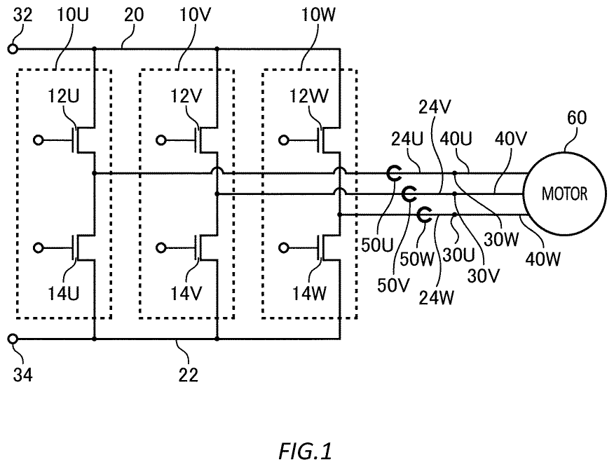

FIG. 1 illustrates an example of a circuit configuration of a power module 100 according to the present embodiment. The power module 100 is a three-phase inverter that converts direct current into three-phase alternating current. Three-phase alternating current output from the power module 100 is supplied to a motor 60 that is a three-phase alternating current motor. The motor 60 may be a power source for a moving body. The power module 100 and the motor 60 may be installed in a moving body such as a hybrid vehicle or electric vehicle. The power module 100, depending on its application, may be a single-phase inverter that converts direct current to alternating current.

The power module 100 includes a U-phase circuit 10U, a V-phase circuit 10V, and a W-phase circuit 10W. The U-phase circuit 10U has a high side power semiconductor 12U and a low side power semiconductor 14U coupled in series. A source or an emitter of the power semiconductor 12U and a drain or a collector of the power semiconductor 14U are electrically coupled. For example, when the power semiconductor 12U and the power semiconductor 14U is a MOSFET, the source of the power semiconductor 12U and the drain of the power semiconductor 14U are electrically coupled. For example, when the power semiconductor 12U and the power semiconductor 14U is an IGBT, the emitter of the power semiconductor 12U and the collector of the power semiconductor 14U are electrically coupled. In the present invention, a first terminal is the drain or the collector in an example, and a second terminal is the source or the emitter in an example.

The V-phase circuit 10V has a high side power semiconductor 12V and a low side power semiconductor 14V coupled in series. A source or an emitter of the power semiconductor 12V and a drain or a collector of the power semiconductor 14V are electrically coupled. The W-phase circuit 10W has a high side power semiconductor 12W and a low side power semiconductor 14W coupled in series. A source or an emitter of the power semiconductor 12W and a drain or a collector of the power semiconductor 14W are electrically coupled.

The power module 100 includes a pair of direct current terminals 32, 34, and a U-phase terminal 30U, a V-phase terminal 30V, and a W-phase terminal 30W (may be collectively referred to as a terminal 30). The direct current terminal 32 is an example of a second external terminal. The direct current terminal 34 is an example of a third external terminal. Further, the U-phase terminal 30U, the V-phase terminal 30V, and the W-phase terminal 30W are examples of a first external terminal. The power module 100 further has a high side conductor 20 electrically coupled to the direct current terminal 32, and a low side conductor 22 electrically coupled to the direct current terminal 34. The conductor 20 is an example of a third conductor. The conductor 22 is an example of a second conductor. The conductor 20 and the conductor 22 may be configured by a conductor material principally made of copper.

The U-phase circuit 10U, the V-phase circuit 10V, and the W-phase circuit 10W are coupled in parallel between the conductor 20 and the conductor 22. Drains or collectors of the high side power semiconductors 12U, 12V, 12W (may be collectively referred to as a power semiconductor 12) are electrically coupled to the conductor 20. Sources or emitters of the low side power semiconductors 14U, 14V, 14W (may be collectively referred to as a power semiconductor 14) are electrically coupled to the conductor 22.

The power module 100 further includes a conductor 24U electrically coupled to the U-phase terminal 30U, a conductor 24V electrically coupled to the V-phase terminal 30V, and a conductor 24W electrically coupled to the W-phase terminal 30W. The source or the emitter of the power semiconductor 12U and the drain or the collector of the power semiconductor 14U are electrically coupled to the conductor 24U. The source or the emitter of the power semiconductor 12V and the drain or the collector of the power semiconductor 14V are electrically coupled to the conductor 24V. The source or the emitter of the power semiconductor 12W and the drain or the collector of the power semiconductor 14W are electrically coupled to the conductor 24W.

The conductors 24U, 24V, and 24W (may be collectively referred to as a conductor 24) are electrically coupled to the motor 60 via busbars 40U, 40V, 40W. The conductors 24U, 24V, and 24W are provided on an insulating substrate 11. The conductors 24U, 24V, and 24W are examples of a first conductor. The conductor 24 may be configured by a conductor material principally made of copper.

The power module 100 further includes current sensors 50U, 50V, 50W (may be collectively referred to as a current sensor 50). The current sensor 50U measures a current value of a U-phase current flowing through the conductor 24U. The current sensor 50V measures a current value of a V-phase current flowing through the conductor 24V. The current sensor 50W measures a current value of a W-phase current flowing through the conductor 24W.

The current sensors 50U, 50V, 50W may each be a magnetic sensor having at least one magnetoelectric conversion element that detects a magnitude of a magnetic field or a change of a magnetic field generated by the respective U-phase current, V-phase current, W-phase current flowing through the conductors 24U, 24V, 24W. The current sensors 50U, 50V, 50W each further has a signal processing IC that outputs a signal representing the current value of the respective U-phase current, V-phase current, W-phase current, which corresponds to the magnitude of the magnetic field and is output from the at least one magnetoelectric conversion element. The signal processing IC is a large scale integration (LSI). The signal processing IC is a monolithic IC. More specifically, the signal processing IC is a signal processing circuit formed of a Si monolithic semiconductor formed on a Si substrate. The signal processing IC may have a circuit surface on which the at least one magnetoelectric conversion element is arranged. The current sensors 50U, 50V, 50W may each be a semiconductor package in which the at least one magnetoelectric conversion element and the signal processing IC are encapsulated by a mold resin. The at least one magnetoelectric conversion element and the signal processing IC may not be encapsulated by the mold resin. The current sensors 50U, 50V, 50W may each be a current sensor in which the at least one magnetoelectric conversion element and the signal processing IC are exposed on an insulating substrate. The at least one magnetoelectric conversion element may be electrically coupled to the signal processing IC by wire bonding.

The current sensors 50U, 50V, 50W each has a terminal 55 for outputting the signal processed by the signal processing IC as a current respectively to external input/output conductors 70U, 70V, 70W. The terminal 55 may be exposed on a surface of each of the current sensors 50U, 50V, 50W, and may protrude from the surface of each of the current sensors 50U, 50V, 50W. The current sensors 50U, 50V, 50W each functions as a current sensor by detecting, with the at least one magnetoelectric conversion element, the magnitude of the magnetic field or the change of the magnetic field generated by the respective U-phase current, V-phase current, W-phase current flowing through the conductors 24U, 24V, 24W; outputting, from the signal processing IC, the signal which corresponds to the magnitude of the magnetic field and is output from the magnetoelectric conversion element as the signal representing the current value of the respective U-phase current, V-phase current, W-phase current; and outputting the signal via the terminal 55 to the respective input/output conductors 70U, 70V, 70W.

The current sensors 50U, 50V, 50W may be coreless current sensors. In the present specification, the coreless current sensor is a sensor having at least one magnetoelectric conversion element that detects a magnitude of a magnetic field or a change of a magnetic field generated by a current flowing through a conductor, and is a current sensor that does not have a magnetic core arranged around a magnetic sensor or surrounding a current conductor.

In the present embodiment, in the power module 100 configured in this manner, the current sensors 50U, 50V, 50W are provided within the power module 100 while suppressing an increase in size.

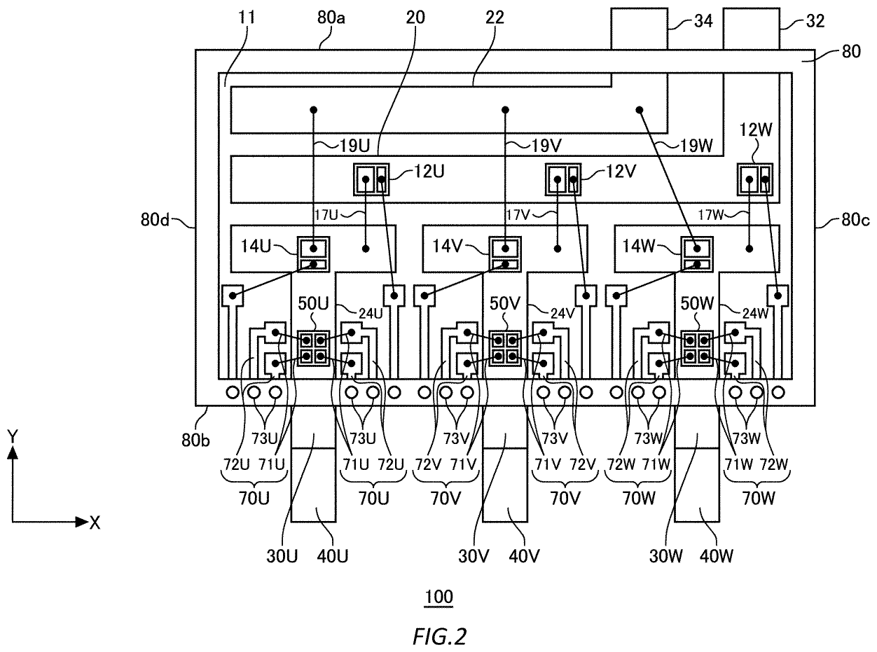

FIG. 2 is a plan view schematically illustrating an example of an internal configuration of the power module 100 according to the present embodiment.

The power module 100 includes the insulating substrate 11, and the conductor 20, 22, the U-phase conductor 24U, the V-phase conductor 24V, the W-phase conductor 24W, the power semiconductors 12U, 14U, 12V, 14V, 12W, 14W, and the current sensors 50U, 50V, 50W provided on the insulating substrate 11.

The insulating substrate 11, the conductors 20, 22, the U-phase conductor 24U, the V-phase conductor 24V, the W-phase conductor 24W, the power semiconductors 12U, 14U, 12V, 14V, 12W, 14W, and the current sensors 50U, 50V, 50W are encapsulated by an encapsulating portion 80 configured by being filled with an insulating resin. For example, the insulating resin may be an epoxy resin, a silicone gel, or the like.

The pair of direct current terminals 32, 34 is exposed from one side surface 80a
of the encapsulating portion 80. The U-phase terminal 30U, the V-phase terminal 30V, and the W-phase terminal 30W are exposed from a side surface 80b on an opposite side of the side surface 80a of the encapsulating portion 80.

Herein, a direction from the side surface 80b toward the side surface 80a along the insulating substrate 11 is referred to as a first direction (Y axis direction). A direction along the insulating substrate 11 that intersects the first direction is referred to as a second direction (X axis direction).

The conductor 20 is coupled to the direct current terminal 32, and the conductor 22 is coupled to the direct current terminal 34. The conductor 20 and the conductor 22 may be wiring patterns provided on the insulating substrate 11. The conductor 20 extends from the direct current terminal 32 along the first direction from the side surface 80a toward the side surface 80b, and further extends from a side surface 80c side toward a side surface 80d, on an opposite side of the side surface 80c, along the second direction. The conductor 22 extends from the direct current terminal 34 along the first direction from the side surface 80a toward the side surface 80b, and further extends from the side surface 80c side toward the side surface 80d along the second direction. The conductor 20 and the conductor 22 extend parallel to each other at an interval in the plan view. It is to be noted that shapes of the conductor 20 and the conductor 22 are merely examples, and may be another shape.

The power semiconductors 12U, 12V, 12W are arranged via a conductive adhesive on the conductor 20. The drains or the collectors of the power semiconductors 12U, 12V, 12W are electrically coupled to the conductor 20 via the conductive adhesive. The sources or the emitters of the power semiconductors 12U, 12V, 12W are electrically coupled respectively to the conductors 24U, 24V, 24W via wires 17U, 17V, 17W. The power semiconductors 12U, 12V, 12W are examples of a second power semiconductor. The wires 17U, 17V, 17W may be formed of a conductor material principally made of Au, Ag, Cu, or Al.

The conductor 24U is coupled to the U-phase terminal 30U, the conductor 24V is coupled to the V-phase terminal 30V, and the conductor 24W is coupled to the W-phase terminal 30W.

The conductors 24U, 24V, 24W extend along the insulating substrate 11 from the side surface 80b toward the side surface 80a in the first direction. The conductors 24U, 24V, 24W may be wiring patterns provided on the insulating substrate 11. A portion extending along the second direction to the side surface 80c and side surface 80d sides may be provided on an end of each of the conductors 24U, 24V, 24W on an opposite side of the U-phase terminal 30U, the V-phase terminal 30V, and the W-phase terminal 30W.

The power semiconductors 14U, 14V, 14W are arranged via a conductive adhesive on the conductors 24U, 24V, 24W. The drains or the collectors of the power semiconductors 14U, 14V, 14W are electrically coupled to the conductors 24U, 24V, 24W via the conductive adhesive. The sources or the emitters of the power semiconductors 14U, 14V, 14W are electrically coupled to the conductor 22 via wires 19U, 19V, 19W. The power semiconductors 14U, 14V, 14W are examples of a first power semiconductor. The wires 19U, 19V, 19W may be formed of a conductor material principally made of Au, Ag, Cu, or Al.

The current sensors 50U, 50V, 50W are arranged on the conductors 24U, 24V, 24W via an insulator.

In the power module 100 configured in this manner, in the plan view, the current sensors 50U, 50V, 50W are arranged between the U-phase terminal 30U, the V-phase terminal 30V, the W-phase terminal 30W, and the power semiconductors 14U, 14V, 14W in the first direction.

The current sensors 50U, 50V, 50W are arranged such that, in the plan view, they are at least partially overlapped with the conductors 24U, 24V, 24W, which are electrically coupled to the power semiconductors 14U, 14V, 14W and extend in the first direction, or are surrounded by the conductors 24U, 24V, 24W. In this way, the current sensors 50U, 50V, 50W can precisely detect a magnitude of a magnetic field generated by a current flowing through the conductors 24U, 24V, 24W. When the current sensors 50U, 50V, 50W have a longitudinal magnetic field detection type element such as a Hall element as the magnetoelectric conversion element, the current sensors 50U, 50V, 50W may be arranged such that, in the plan view, they are at least partially surrounded by the conductors 24U, 24V, 24W. When the current sensors 50U, 50V, 50W have a transverse magnetic field detection type element such as a magneto-resistance element as the magnetoelectric conversion element, the current sensors 50U, 50V, 50W may be arranged such that, in the plan view, they are at least partially overlapped with the conductors 24U, 24V, 24W. The current sensors 50U, 50V, 50W may be arranged such that, in the plan view, their magnetic sensitive surfaces are at least partially overlapped with the conductors 24U, 24V, 24W.

When the current sensors 50U, 50V, 50W are arranged between the U-phase terminal 30U, the V-phase terminal 30V, the W-phase terminal 30W and the power semiconductors 14U, 14V, 14W, the current sensors 50U, 50V, 50W can detect currents flowing close to the U-phase terminal 30U, the V-phase terminal 30V, the W-phase terminal 30W. In addition, in the plan view, by arranging the current sensors 50U, 50V, 50W on paths of the conductors 24U, 24V, 24W extending in the first direction overlapping with the power semiconductors 14U, 14V, 14W, the power semiconductors 14U, 14V, 14W and the current sensors 50U, 50V, 50W can be arranged without wasting space. Thus, the power module 100 can be miniaturized.

The power module 100 further has input/output terminals 73U, 73V, 73W exposed from the encapsulating portion 80 and electrically coupled to terminals of the current sensors 50U, 50V, 50W. The input/output terminals 73U, 73V, 73W may extend toward a surface on an opposite side of the surface on which the insulating substrate 11 of the encapsulating portion 80 is arranged, and be electrically coupled to another substrate arranged on the surface on the opposite side of the surface on which the insulating substrate 11 of the encapsulating portion 80 is arranged.

The plurality of input/output terminals 73U, 73V, 73W are exposed on the side surface 80b side which is the same as the U-phase terminal 30U, the V-phase terminal 30V, the W-phase terminal 30W. The plurality of input/output terminals 73U, 73V, 73W are arranged, in the plan view, at positions not overlapping with the U-phase terminal 30U, the V-phase terminal 30V, the W-phase terminal 30W.

The power module 100 further has a plurality of the input/output conductors 70U, 70V, 70W (may be collectively referred to as an input/output conductor 70) that electrically couple the input/output terminals 73U, 73V, 73W to the current sensors 50U, 50V, 50W. The plurality of input/output conductors 70U, 70V, 70W convey signals output from the current sensors 50U, 50V, 50W. A part of the plurality of input/output conductors 70U, 70V, 70W may be power supply lines for the current sensors 50U, 50V, 50W.

The input/output conductors 70U, 70V, 70W have first portions 71U, 71V, 71W (may be collectively referred to as a first portion 71) extending, in the plan view, in a direction intersecting the first direction and electrically coupled to the current sensor 50, and second portions 72U, 72V, 72W (may be collectively referred to as a second portion 72) coupled to the first portions 71U, 71V, 71W and the input/output terminals 73U, 73V, 73W. The second portions 72U, 72V, 72W may be wiring patterns provided on the insulating substrate 11, and may be provided at least in part along the conductors 24U, 24V, 24W. The first portions 71U, 71V, 71W may be wires electrically connecting terminals of the current sensors 50U, 50V, 50W to the second portions 72U, 72V, 72W. The input/output terminals 73U, 73V, 73W includes input terminals and output terminals. The power module 100 may include at least one pair of an input terminal and an output terminal exposed from the encapsulating portion 80; an input conductor having a part of the first portions 71U, 71V, 71W which extends in the second direction extending along the insulating substrate 11 and intersecting the first direction in the plan view and is electrically coupled to the current sensors 50U, 50V, 50W, and a part of the second portions 72U, 72V, 72W coupled to the part of the first portions 71U, 71V, 71W and the input terminal; and an output conductor having another part of the first portions 71U, 71V, 71W which extends in the second direction extending along the insulating substrate 11 and intersecting the first direction in the plan view and is electrically coupled to the current sensors 50U, 50V, 50W, and another part of the second portions 72U, 72V, 72W coupled to the other part of the first portions 71U, 71V, 71W and the output terminal.

The first portions 71U, 71V, 71W may not necessarily be in the second direction perpendicular to the first direction in the plan view, as long as they are not in the first direction. When the input/output conductors 70U, 70V, 70W has the first portions 71U, 71V, 71W, the input/output terminals 73U, 73V, 73W and the U-phase terminal 30U, the V-phase terminal 30V, the W-phase terminal 30W can be exposed from the encapsulating portion 80 without overlapping in the plan view. Further, by providing the second portions 72U, 72V, 72W along the conductors 24U, 24V, 24W extending in the first direction, a space saving effect can be achieved. Thus, the power module 100 can be miniaturized.

In addition, complication of structure due to incorporation of the current sensor 50 in the power module 100 does not occur, simplification can be achieved, and a number of parts can be reduced. Further, even when a distance between the current sensor 50 and the conductor 24 is reduced, insulation can be maintained by the insulating resin configuring an insulator 56 and the encapsulating portion 80. In addition, by arranging the magnetoelectric conversion element and the signal processing IC close to each other, influence of their individual temperature distributions within the power module 100 can be reduced, and precision of temperature correction can be improved.

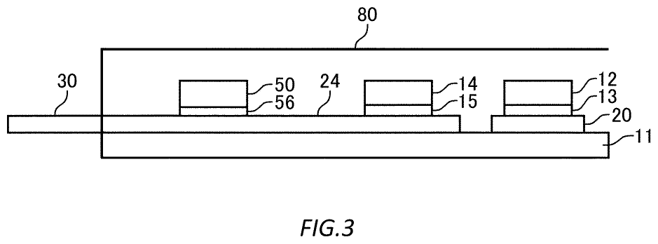

FIG. 3 schematically illustrates a part of a cross-sectional view of the power module 100 viewed from a side surface side in the X direction. The current sensor 50 may be arranged on the conductor 24 via the insulator 56. The power semiconductor 14 may be arranged on the conductor 24 via a conductive adhesive 15. The drain or the collector of the power semiconductor 14 is electrically coupled to the conductor 24 via the conductive adhesive 15. The power semiconductor 12 may be arranged on the conductor 20 via a conductive adhesive 13. As described above, by arranging the current sensor 50 between the terminal 30 and the power semiconductor 14 along a current path of the conductor 24, the current sensor 50 can be arranged close to the terminal 30.

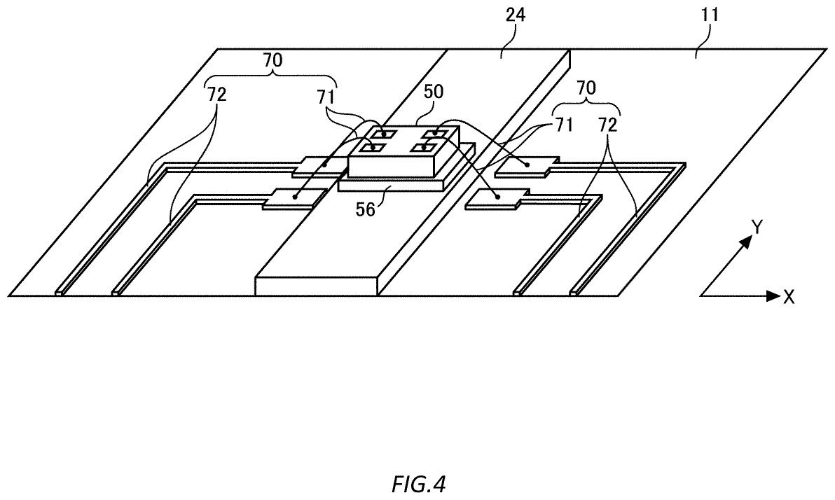

FIG. 4 is a perspective view schematically illustrating the current sensor 50, the conductor 24, and the input/output conductor 70. The first portion 71 that is a wire for electrically coupling the current sensor 50 to the input/output conductor 70 extends toward the second direction (X axis direction) different from the first direction (Y axis direction) that is along the current path of the conductor 24, and is electrically coupled to the second portion 72 that is a wiring pattern beside the conductor 24. When the input/output conductor 70 is exposed from a side portion of the encapsulating portion 80 on a same side as the terminal 30, a space for arranging the second portion 72 can be reduced.

In the example illustrated in FIG. 3 and FIG. 4, the conductor 24 is formed as a wiring pattern on the insulating substrate 11. On the other hand, the conductor 24 may be a part of a busbar directly coupled from the terminal 30.

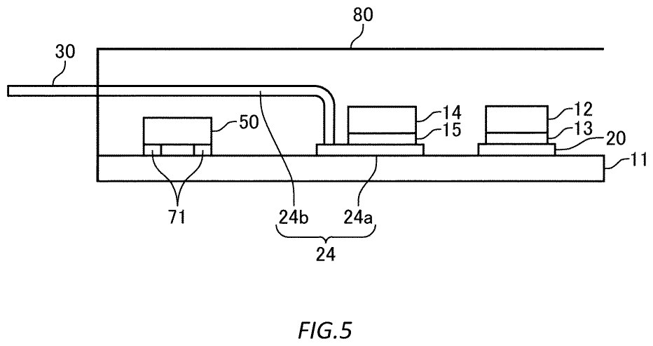

FIG. 5 is a drawing according to a modified example schematically illustrating a part of a cross-sectional view of the power module 100 from the side surface side in the X direction. In the example illustrated in FIG. 3, all of the conductor 24 is provided as a wiring pattern on the insulating substrate 11. In the modified example, a part of the conductor 24 is not a wiring pattern provided on the insulating substrate 11. The conductor 24 has a conductor 24a that is a wiring pattern electrically coupled to the drain or the collector on a bottom side of the power semiconductor 14 on the insulating substrate 11, and a conductor 24b that is a metal plate electrically coupled to the conductor 24a. The source or the emitter on a ceiling surface side of the power semiconductor 14 is, similarly to the embodiment illustrated in FIG. 2, electrically coupled to the conductor 22 via the wire 19. The conductor 24b is arranged on an opposite side of the insulating substrate 11 when viewed from the current sensor 50 in a side view, and is physically and electrically coupled to the conductor 24a on the insulating substrate 11 surface. A coupling method of the conductor 24a and the conductor 24b may be, for example, welding or the like. The conductor 24 having the conductor 24a and the conductor 24b is an example of the first conductor. The drain or the collector on the bottom side of the power semiconductor 14 is electrically coupled to the conductor 24a via the conductive adhesive 15. The conductor 24b may be, for example, a part of a busbar directly coupled from the terminal 30.

As illustrated in FIG. 5, a measurement current measured by the current sensor 50 may flow through the conductor 24b arranged on the opposite side of the insulating substrate 11, instead of through the insulating substrate 11 side, when viewed from the side surface side.

As illustrated in FIG. 5, the conductor 24 and the current sensor 50 may be insulated from each other by encapsulating the conductor 24 and the current sensor 50 in the insulating resin in a state in which they are physically separated from each other.

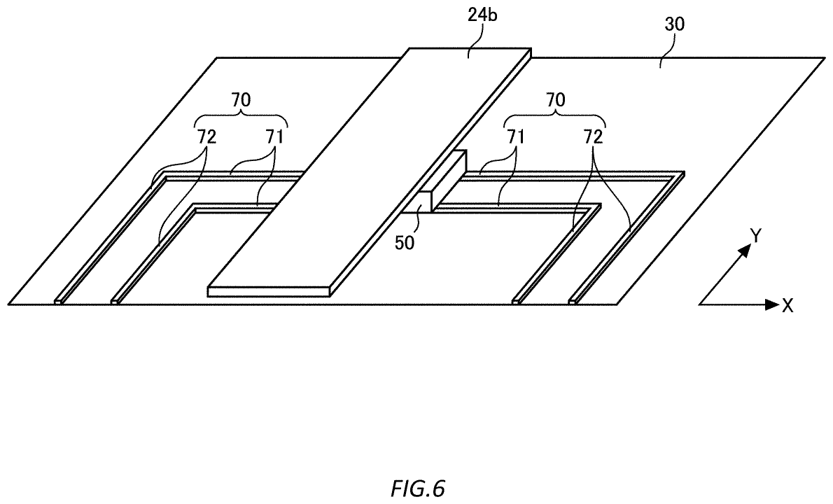

FIG. 6 is a perspective view schematically illustrating the current sensor 50, the conductor 24b, and the input/output conductor 70 in the modified example illustrated in FIG. 5. In the embodiment illustrated in FIG. 4, coupling terminals of the current sensor 50 are arranged on a surface on an opposite side of the insulating substrate 11 side. On the other hand, in the modified example, the current sensor 50 is arranged on the insulating substrate 11 side, and the current sensor 50 is electrically coupled to the first portion 71 that is arranged as a wiring pattern on the insulating substrate 11. The input/output conductor 70 is arranged as both the first portion 71 and the second portion 72 being a wiring pattern on the insulating substrate 11. Even when the first portion 71 is arranged on the insulating substrate 11 as a wiring pattern, the first portion 71 extends in the second direction intersecting the first direction in the plan view, and is electrically coupled to the current sensor 50. When the first portion 71 on the insulating substrate 11 extends in the second direction and the second portion 72 extends in the first direction, input/output terminals electrically coupled to the input/output conductor 70 and the terminal 30 can be exposed from the encapsulating portion 80 without overlapping in the plan view. By providing the second portion 72 along the conductor 24 extending in the first direction, a space saving effect can be achieved. Thus, the power module 100 can be miniaturized.

In the above-described example, in the plan view, the current sensor 50 is arranged at a position overlapping with the conductor 24, and a portion of the conductor 24 extending in the first direction has a linear shape. However, the shape of the conductor 24 may be another shape.

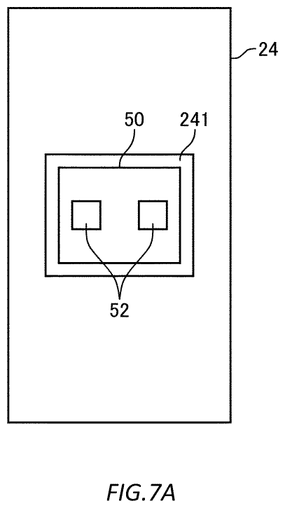

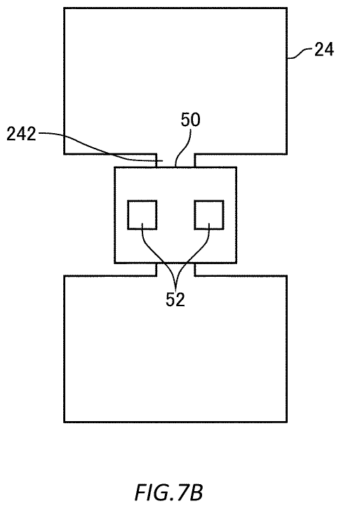

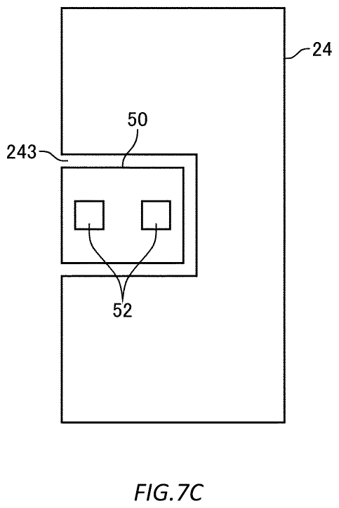

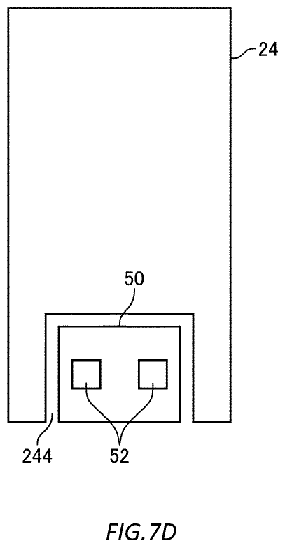

FIG. 7A to FIG. 7D illustrate shapes of the conductor 24 according to modified examples. In FIG. 7A to 7D, the current sensor 50 including two magnetoelectric conversion elements 52 that are Hall elements that are an example of a longitudinal magnetic field detection type element is illustrated as an example. However, the current sensor 50 may include one Hall element, or alternatively include one or more of a transverse magnetic field detection type element such as a magneto-resistance element.

As illustrated in FIG. 7A, the conductor 24 may have an aperture 241 at a position facing the current sensor 50 in the plan view, the current sensor 50 may be arranged within the aperture 241, and the current sensor 50 may be arranged on the insulating substrate 11 not via the conductor 24. In a state in which the two magnetoelectric conversion elements 52 facing each other in a direction intersecting a direction in which a current flows through the conductor 24, the current sensor 50 is arranged such that it is surrounded by the conductor 24 in the plan view. The current sensor 50 may be at least partially overlapped with the conductor 24 in the side view. Alternatively, the current sensor 50 may not be overlapped with the conductor 24 in the side view. That is, when viewed from the side surface side, the current sensor 50 may be arranged between the insulating substrate 11 and the conductor 24.

As illustrated in FIG. 7B, the conductor 24 may have a portion 242 that is more narrow than other portions and is narrower than a width of the current sensor 50 in the plan view, and the current sensor 50 may be provided at a position overlapping with the portion 242 in the plan view. The current sensor 50 is arranged such that it is partially overlapped with the conductor 24 in the plan view. The current sensor 50 may be at least partially overlapped with the conductor 24 when view from the side surface side. Alternatively, the current sensor 50 may not be overlapped with the conductor 24 in the side view. That is, in the side view, the current sensor 50 may be arranged between the insulating substrate 11 and the conductor 24.

As illustrated in FIG. 7C and FIG. 7D, the conductor 24 may have a notch 243 on a side in a longitudinal direction or a side in a lateral direction of the conductor 24, the current sensor 50 may be arranged within the notch 243, and the current sensor 50 may be arranged on the insulating substrate 11 not via the conductor 24. The current sensor 50 is arranged such that it is partially surrounded by the conductor 24 in the plan view.

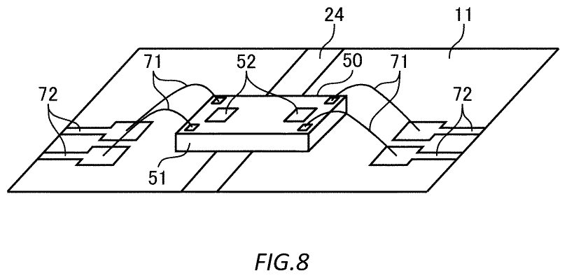

The current sensor 50 may be exposed with the magnetoelectric conversion element 52 not encapsulated by a mold resin. As illustrated in FIG. 8, a signal processing IC 51 and the magnetoelectric conversion element 52 are each configured by a chip, and the magnetoelectric conversion element 52 may be arranged on the chip of the signal processing IC 51. The magnetoelectric conversion element 52 may be arranged on a surface on which a terminal of the chip of the signal processing IC 51 is provided. The above-described arrangement includes arranging the magnetoelectric conversion element 52 as a chip on the chip of the signal processing IC 51, forming the magnetoelectric conversion element 52 on the signal processing IC 51 by vapor deposition, forming the magnetoelectric conversion element 52 on a surface of the signal processing IC 51 as a doped layer, or the like.

When the signal processing IC 51 and the magnetoelectric conversion element 52 are a semiconductor package encapsulated by a mold resin, it may have any type of terminal, and may be, for example, SOP, SON, QFN.

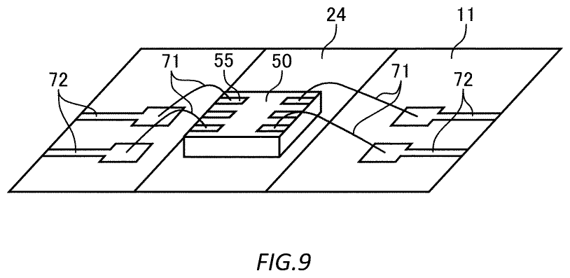

Even when the current sensor 50 is configured by a terminal type such as SOP, SON, QFN, the current sensor 50 may be electrically coupled to the input/output conductor 70 by a wire and not a wiring pattern on the insulating substrate 11. For example, as illustrated in FIG. 9, a surface on which the terminal 55 of the current sensor 50 is provided may be arranged on an opposite side of the conductor 24 on the insulating substrate 11, and the second portion 72 of the input/output conductor 70 on the insulating substrate 11 and the terminal 55 of the current sensor 50 may be electrically coupled via a wire 71. It is to be noted that in the embodiment illustrated in FIG. 9, a surface on which the terminal 55 of the current sensor 50 is not provided may be arranged on the conductor 24 via an insulator such as a die attach film.

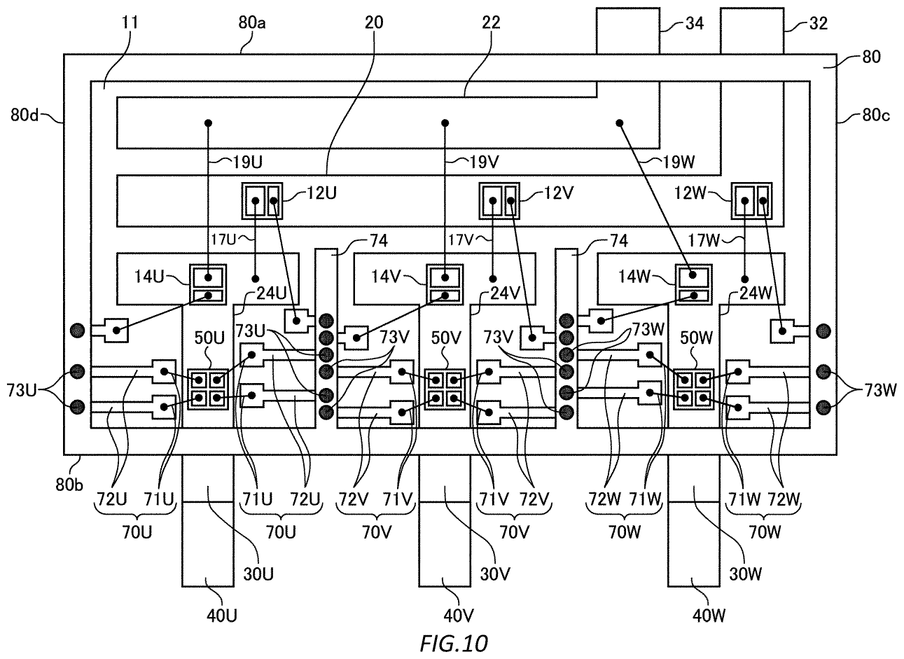

FIG. 10 is a plan view schematically illustrating an example of an internal configuration of the power module 100 according to a first modified example of the present embodiment.

In the first modified example, the plurality of input/output terminals 73U, 73V, 73W are the same as in the power module 100 illustrated in FIG. 2 in that they extend toward an opposite side of a surface on which the insulating substrate 11 of the encapsulating portion 80 is arranged, and are electrically coupled to another substrate arranged on a surface on an opposite side of the surface on which the insulating substrate 11 of the encapsulating portion 80 is arranged.

On the other hand, in the first modified example, positions where the plurality of input/output terminals 73U, 73V, 73W are exposed from the encapsulating portion 80 differs from the power module 100 illustrated in FIG. 2. The plurality of input/output terminals 73U, 73V, 73W are, for example, pins.

Specifically, the encapsulating portion 80 has a partition portion 74 between the conductor 24U and the conductor 24V along a direction in which the conductor 24U and the conductor 24V extend which separates the conductor 24U and the conductor 24V, and the partition portion 74 between the conductor 24V and the conductor 24W along a direction in which the conductor 24V and the conductor 24W extend which separates the conductor 24V and the conductor 24W. The partition portion 74 extends from a side wall of the encapsulating portion 80. The partition portion 74 may extend from a side wall where the side surface 80b of the encapsulating portion 80 is located toward a side wall where a side surface 80a of the encapsulating portion 80 is located.

A part of the plurality of input/output terminals 73U is exposed from the partition portion 74 between the conductor 24U and the conductor 24V, and another part of the plurality of input/output terminals 73U is exposed from a side wall where a side surface 80d of the encapsulating portion 80 is located. The positions where the part of the plurality of input/output terminals 73U and the other part of the plurality of input/output terminals 73U are exposed are closer to the side surface 80b side of the encapsulating portion 80 where a busbar 40U is exposed than the power semiconductor 12U and the power semiconductor 14U in the plan view.

A part of the plurality of input/output terminals 73V is exposed from the partition portion 74 between the conductor 24U and the conductor 24V, and another part of the plurality of input/output terminals 73V is exposed from the partition portion 74 between the conductor 24V and the conductor 24W. The positions where the part of the plurality of input/output terminals 73V and the other part of the plurality of input/output terminals 73V are exposed are closer the side surface 80b side of the encapsulating portion 80 where a busbar 40V is exposed than the power semiconductor 12V and the power semiconductor 14V in the plan view.

A part of the plurality of input/output terminals 73W is exposed from the partition portion 74 between the conductor 24V and the conductor 24W, and another part of the plurality of input/output terminals 73W is exposed from a side wall where a side surface 80c of the encapsulating portion 80 is located. The positions where the part of the plurality of input/output terminals 73W and the other part of the plurality of input/output terminals 73W are exposed are closer to the side surface 80b side of the encapsulating portion 80 where a busbar 40W is exposed than the power semiconductor 12W and the power semiconductor 14W in the plan view.

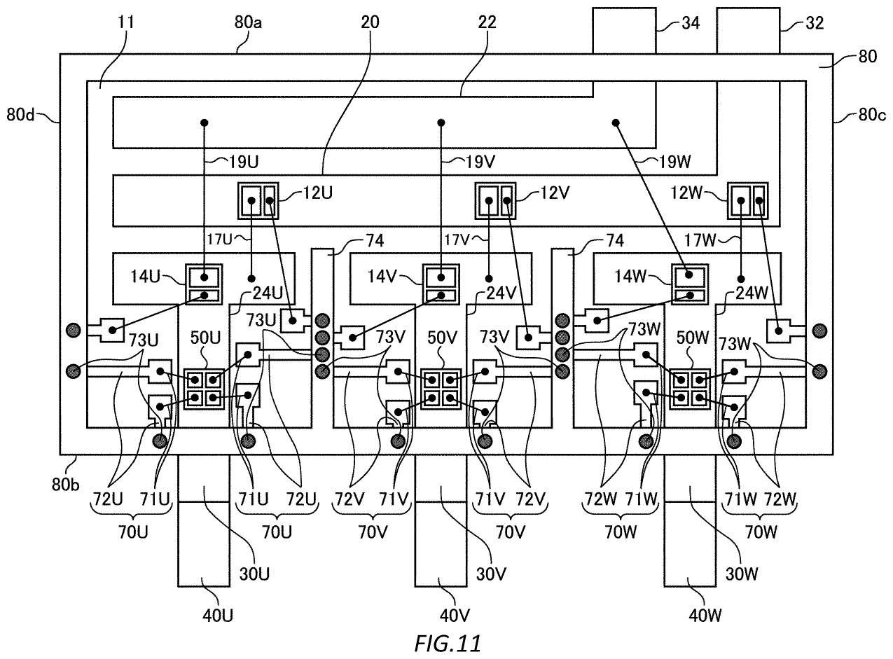

FIG. 11 is a plan view schematically illustrating an example of an internal configuration of the power module 100 according to a second modified example of the present embodiment.

In the second modified example, the plurality of input/output terminals 73U, 73V, 73W are the same as in the power module 100 illustrated in FIG. 2 in that they extend toward an opposite side of a surface on which the insulating substrate 11 of the encapsulating portion 80 is arranged, and are electrically coupled to another substrate arranged on a surface on an opposite side of the surface on which the insulating substrate 11 of the encapsulating portion 80 is arranged.

On the other hand, in the second modified example, positions where the plurality of input/output terminals 73U, 73V, 73W are exposed from the encapsulating portion 80 differs from the power module 100 illustrated in FIG. 2. The plurality of input/output terminals 73U, 73V, 73W are, for example, pins.

Specifically, the encapsulating portion 80 has a partition portion 74 between the conductor 24U and the conductor 24V along a direction in which the conductor 24U and the conductor 24V extend which separates the conductor 24U and the conductor 24V, and the partition portion 74 between the conductor 24V and the conductor 24W along a direction in which the conductor 24V and the conductor 24W extend which separates the conductor 24V and the conductor 24W. The partition portion 74 extends from a side wall of the encapsulating portion 80. The partition portion 74 may extend from a side wall where the side surface 80b of the encapsulating portion 80 is located toward a side wall where a side surface 80a of the encapsulating portion 80 is located.

A part of the plurality of input/output terminals 73U is exposed from the partition portion 74 between the conductor 24U and the conductor 24V, and another part of the plurality of input/output terminals 73U is exposed from a side wall where a side surface 80d of the encapsulating portion 80 is located. Another further part of the plurality of input/output terminals 73U is also exposed from a side wall where the side surface 80b of the encapsulating portion 80 is located. The positions where the part of the plurality of input/output terminals 73U and the other part of the plurality of input/output terminals 73U are exposed are closer to the side surface 80b side of the encapsulating portion 80 where a busbar 40U is exposed than the power semiconductor 12U and the power semiconductor 14U in the plan view.

A part of the plurality of input/output terminals 73V is exposed from the partition portion 74 between the conductor 24U and the conductor 24V, and another part of the plurality of input/output terminals 73V is exposed from the partition portion 74 between the conductor 24V and the conductor 24W. Another further part of the plurality of input/output terminals 73V is also exposed from a side wall where the side surface 80b of the encapsulating portion 80 is located. The positions where the part of the plurality of input/output terminals 73V and the other part of the plurality of input/output terminals 73V are exposed are closer to the side surface 80b side of the encapsulating portion 80 where a busbar 40V is exposed than the power semiconductor 12V and the power semiconductor 14V in the plan view.

A part of the plurality of input/output terminals 73W is exposed from the partition portion 74 between the conductor 24V and the conductor 24W, and another part of the plurality of input/output terminals 73W is exposed from a side wall where a side surface 80c of the encapsulating portion 80 is located. Another further part of the plurality of input/output terminals 73W is also exposed from a side wall where the side surface 80b of the encapsulating portion 80 is located. The positions where the part of the plurality of input/output terminals 73W and the other part of the plurality of input/output terminals 73W are exposed are closer to the side surface 80b side of the encapsulating portion 80 where a busbar 40W is exposed than the power semiconductor 12W and the power semiconductor 14W in the plan view.

As shown in the first modified example and the second modified example above, the positions where the plurality of input/output terminals 73U, 73V, 73W are exposed may be a position other than the side wall where the side surface 80b of the encapsulating portion 80 is located, as long as they are closer to the side surface 80b side of the encapsulating portion 80 where the busbars 40U, 40V, 40W are exposed than the power semiconductors 12U, 12V, 12W and the power semiconductors 14U, 14V, 14W.

While the present invention has been described above by using the embodiments, the technical scope of the present invention is not limited to the above-described embodiments. It is apparent to persons skilled in the art that various alterations or improvements can be made to the above-described embodiments. It is also apparent from description of the claims that the embodiments to which such alterations or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described by using phrases such as “first” or “next” for the sake of convenience in the claims, specification, or drawings, it does not necessarily mean that the process must be performed in this order.

[Item 1] A power module, comprising:
an insulating substrate;
a first power semiconductor mounted on the insulating substrate;
a first conductor at least partially overlapped with the first power semiconductor in a plan view, electrically coupled to a first terminal of the first power semiconductor, and extending along a surface of the insulating substrate in a first direction;
a current sensor which is arranged to be at least partially overlapped with or at least partially surrounded by the first conductor in the plan view, and outputs a signal corresponding to a magnitude of a magnetic field generated by a measurement current flowing through the first conductor as a signal representing a current value of the measurement current;
an encapsulating portion which encapsulates the insulating substrate, the first power semiconductor, the first conductor, and the current sensor, in a state in which the first conductor and the current sensor are insulated from each other; and
a first external terminal electrically coupled to the first conductor and exposed from the encapsulating portion, wherein
the current sensor is arranged between the first external terminal and the first power semiconductor in the first direction in the plan view.

[Item 2] The power module according to item 1, further comprising
at least one pair of input/output terminals exposed from the encapsulating portion, and
at least one pair of input/output conductors which has a first portion which extends in a second direction extending along the insulating substrate and intersecting the first direction in the plan view and is electrically coupled to the current sensor, and has a second portion which is coupled to at least one of the first portion or the at least one pair of input/output terminals, and conveys the signal output from the current sensor, wherein
the second portion does not overlap with the first conductor in the plan view.

[Item 3] The power module according to item 2, wherein
the first external terminal is exposed at a first side surface of the encapsulating portion, and
the at least one pair of input/output terminals is exposed from the encapsulating portion at a position closer to a first side surface side of the encapsulating portion than the first power semiconductor.

[Item 4] The power module according to item 2, wherein
the first external terminal and the at least one pair of input/output terminals are exposed at a first side surface side of the encapsulating portion, and
at least a part of the second portion extends along the first direction.

[Item 5] The power module according to item 2, wherein
the first portion is a wire,
the second portion is a conductive pattern provided on the insulating substrate, and
the current sensor is electrically coupled to the conductive pattern via the wire.

[Item 6] The power module according to item 2, wherein
the first portion and the second portion are conductive patterns provided on the insulating substrate, and
the current sensor is soldered or flip-chip bonded to the first portion.

[Item 7] The power module according to item 1, wherein
the first power semiconductor is arranged on the first conductor. [Item 8] The power module according to item 1, wherein
the first conductor is provided on the insulating substrate.

[Item 9] The power module according to item 1, further comprising
an insulating layer between the current sensor and the first conductor.

[Item 10] The power module according to item 9, wherein
the insulating layer is an adhesive for bonding the current sensor and the first conductor to each other.

[Item 11] The power module according to item 9, wherein
the insulating layer is an insulating resin configuring the encapsulating portion.

[Item 12] The power module according to item 1, wherein
the current sensor has at least one magnetoelectric conversion element and a signal processing IC which processes a signal output from the at least one magnetoelectric conversion element.

[Item 13] The power module according to item 12, wherein
the current sensor is a coreless current sensor.

[Item 14] The power module according to item 12, wherein
the current sensor is a semiconductor package in which the at least one magnetoelectric conversion element and the signal processing IC are encapsulated by a mold resin.

[Item 15] The power module according to item 12, wherein
the at least one magnetoelectric conversion element is electrically coupled to the signal processing IC by wire bonding.

[Item 16] The power module according to item 14, wherein
the current sensor has two magnetoelectric conversion elements of a longitudinal magnetic field detection type, and
in a state in which the two magnetoelectric conversion elements are facing each other in a second direction extending along the insulating substrate and intersecting the first direction, the current sensor is arranged to be at least partially overlapped with or at least partially surrounded by the first conductor in the plan view.

[Item 17] The power module according to item 14, wherein
the current sensor has at least one magnetoelectric conversion element of a transverse magnetic field detection type, and
the current sensor is arranged such that the at least one magnetoelectric conversion element is overlapped with the first conductor in the plan view.

[Item 18] The power module according to item 1, further comprising
a second power semiconductor having a second terminal electrically coupled to the first terminal of the first power semiconductor and the first conductor,
a second conductor provided on the insulating substrate and electrically coupled to a second terminal of the first power semiconductor,
a third conductor provided on the insulating substrate, at least partially overlapped with the second power semiconductor in the plan view, and electrically coupled to a first terminal of the second power semiconductor,
a second external terminal exposed from the encapsulating portion and electrically coupled to the second conductor, and
a third external terminal exposed from the encapsulating portion and electrically coupled to the third conductor.

[Item 19] The power module according to item 18, comprising
a plurality of the first power semiconductors,
a plurality of the second power semiconductors,
a plurality of the first conductors, and
a plurality of the current sensors.

### EXPLANATION OF REFERENCES

10U: U-phase circuit;
10V: V-phase circuit;
10W: W-phase circuit;
11: insulating substrate;
12U, 12V, 12W: power semiconductor;
14U, 14V, 14W: power semiconductor;
13, 15: conductive adhesive;
17U, 17V, 17W: wire;
19U, 19V, 19W: wire;
24U, 24V, 24W: conductor;
30U: U-phase terminal;
30V: V-phase terminal;
30W: W-phase terminal;
32, 34: direct current terminal;
40U, 40V, 40W: busbar;
50U, 50V, 50W: current sensor;
51: signal processing IC;
52: magnetoelectric conversion element;
55: terminal;
56: insulator;
60: motor;
70U, 70V, 70W: input/output conductor;
73U, 73V, 73W: input/output terminal;
80: encapsulating portion;
100: power module.

What is claimed is:

1. A power module, comprising:
an insulating substrate;
a first power semiconductor mounted on the insulating substrate;
a first conductor at least partially overlapped with the first power semiconductor in a plan view, electrically coupled to a first terminal of the first power semiconductor, and extending along a surface of the insulating substrate in a first direction;
a current sensor which is arranged to be at least partially overlapped with or at least partially surrounded by the first conductor in the plan view, and outputs a signal corresponding to a magnitude of a magnetic field generated by a measurement current flowing through the first conductor as a signal representing a current value of the measurement current;
an encapsulating portion which encapsulates the insulating substrate, the first power semiconductor, the first conductor, and the current sensor, in a state in which the first conductor and the current sensor are insulated from each other; and
a first external terminal electrically coupled to the first conductor and exposed from the encapsulating portion, wherein
the current sensor is arranged between the first external terminal and the first power semiconductor in the first direction in the plan view.

2. The power module according to claim 1, further comprising
at least one pair of input/output terminals exposed from the encapsulating portion, and
at least one pair of input/output conductors which has a first portion which extends in a second direction extending along the insulating substrate and intersecting the first direction in the plan view and is electrically coupled to the current sensor, and has a second portion which is coupled to at least one of the first portion or the at least one pair of input/output terminals, and conveys a signal output from the current sensor, wherein
the second portion does not overlap with the first conductor in the plan view.

3. The power module according to claim 2, wherein
the first external terminal is exposed at a first side surface of the encapsulating portion, and
the at least one pair of input/output terminals is exposed from the encapsulating portion at a position closer to a first side surface side of the encapsulating portion than the first power semiconductor.

4. The power module according to claim 2, wherein
the first external terminal and the at least one pair of input/output terminals are exposed at a first side surface side of the encapsulating portion, and
at least a part of the second portion extends along the first direction.

5. The power module according to claim 2, wherein
the first portion is a wire,
the second portion is a conductive pattern provided on the insulating substrate, and
the current sensor is electrically coupled to the conductive pattern via the wire.

6. The power module according to claim 2, wherein
the first portion and the second portion are conductive patterns provided on the insulating substrate, and
the current sensor is soldered or flip-chip bonded to the first portion.

7. The power module according to claim 1, wherein
the first power semiconductor is arranged on the first conductor.

8. The power module according to claim 1, wherein
the first conductor is provided on the insulating substrate.

9. The power module according to claim 1, further comprising
an insulating layer between the current sensor and the first conductor.

10. The power module according to claim 9, wherein
the insulating layer is an adhesive for bonding the current sensor and the first conductor to each other.

11. The power module according to claim 9, wherein
the insulating layer is an insulating resin configuring the encapsulating portion.

12. The power module according to claim 1, wherein
the current sensor has at least one magnetoelectric conversion element and a signal processing IC which processes a signal output from the at least one magnetoelectric conversion element.

13. The power module according to claim 12, wherein
the current sensor is a coreless current sensor.

14. The power module according to claim 12, wherein
the current sensor is a semiconductor package in which the at least one magnetoelectric conversion element and the signal processing IC are encapsulated by a mold resin.

15. The power module according to claim 12, wherein
the at least one magnetoelectric conversion element is electrically coupled to the signal processing IC by wire bonding.

16. The power module according to claim 14, wherein
the current sensor has two magnetoelectric conversion elements of a longitudinal magnetic field detection type, and
in a state in which the two magnetoelectric conversion elements are facing each other in a second direction extending along the insulating substrate and intersecting the first direction, the current sensor is arranged to be at least partially overlapped with or at least partially surrounded by the first conductor in the plan view.

17. The power module according to claim 14, wherein
the current sensor has at least one magnetoelectric conversion element of a transverse magnetic field detection type, and
the current sensor is arranged such that the at least one magnetoelectric conversion element is overlapped with the first conductor in the plan view.

18. The power module according to claim 1, further comprising
a second power semiconductor having a second terminal electrically coupled to the first terminal of the first power semiconductor and the first conductor,
a second conductor provided on the insulating substrate and electrically coupled to a second terminal of the first power semiconductor,
a third conductor provided on the insulating substrate, at least partially overlapped with the second power semiconductor in the plan view, and electrically coupled to a first terminal of the second power semiconductor,
a second external terminal exposed from the encapsulating portion and electrically coupled to the second conductor, and
a third external terminal exposed from the encapsulating portion and electrically coupled to the third conductor.

19. The power module according to claim 18, comprising
a plurality of the first power semiconductors,
a plurality of the second power semiconductors,
a plurality of the first conductors, and
a plurality of the current sensors.
